(19) United States
(12) Patent Application Publication
(10) Pub. No.: US 2013/0303072 A1
(43) Pub. Date: Nov. 14, 2013

(54) COMPUTER CASE WITH VENTILATION AND HEAT DISSIPATION EFFECTS

(71) Applicant: WEN-HSIEN LAI, Gueishan Hsiang (TW)

(72) Inventor: WEN-HSIEN LAI, Gueishan Hsiang (TW)

(21) Appl. No.: 13/468,035

(22) Filed: May 10, 2012

(51) Int. Cl. H05K 5/02

(52) U.S. Cl. 454/184

(57) ABSTRACT

A computer case with ventilation and heat dissipation effects of the present invention is characterized in that the computer case is assembled by a plate-shaped first and second outer board, plural inner boards, plural sleeves and plural pillars. Upper, lower, left and right sides of the computer case that is assembled by the plate-shaped board material are opened to air, which is able to improve cooling and heat dissipation effects of the computer.

### BACKGROUND OF THE INVENTION

a) Field of the Invention

The present invention relates to a computer case with ventilation and heat dissipation effects, and more particularly to a computer case that is assembled by a plate-shaped board material. b) Description of the Prior Art

An interior of an ordinary computer case contains electronic parts, such as a mother board, hard disk drives, CD-ROM drives and a power supply. Most of the computer cases are a fixed structure; whereas, a computer case can be also dismantled into several parts which are then assembled as an integral structure. However, the abovementioned computer case is not assembled by aluminum plates and upper, lower, left and right sides of the computer case are not opened to air. Therefore, cooling and heat dissipation effects of the computer are inferior.

### SUMMARY OF THE INVENTION

Accordingly, the primary object of the present invention is to provide a computer case with ventilation and heat dissipation effects that is assembled by plural plates of a board material. Upper, lower, left and right sides of the computer case are opened to air to improve the cooling and heat dissipation effects of the computer.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows an elevational view according to the present invention.

FIG. 2 shows an exploded elevational view according to the present invention.

FIG. 3 shows an elevational view illustrating functionality according to the present invention.

FIG. 4 shows an exploded elevational view illustrating functionality according to the present invention.

### DETAILED DESCRIPTION OF THE PREFERRED EMBODIMENTS

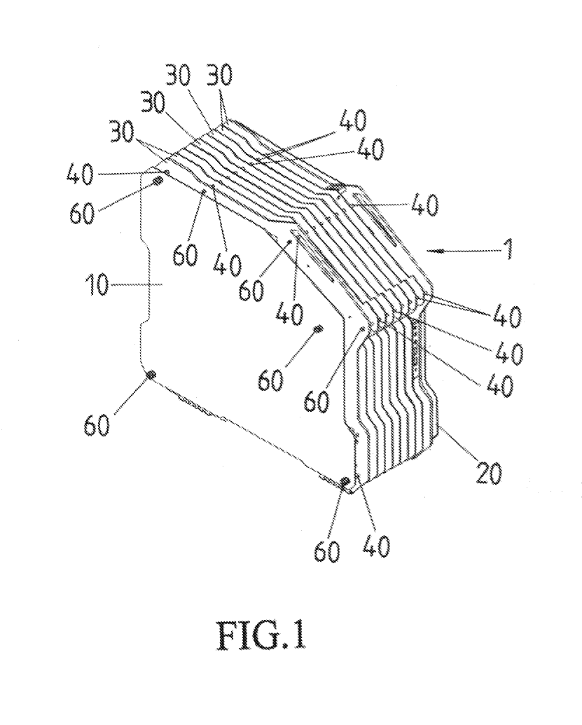

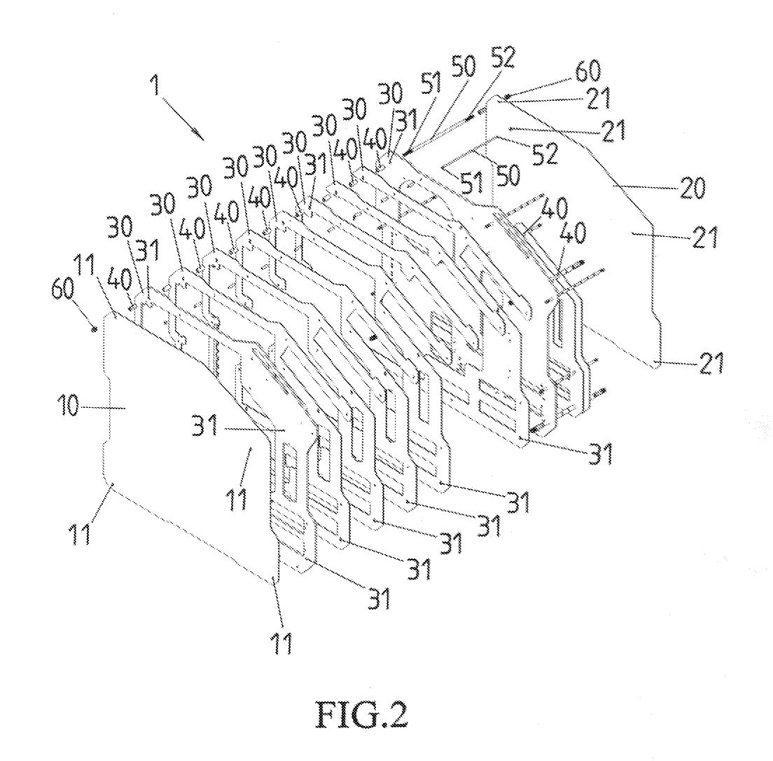

As shown in FIG. 1 and FIG. 2, a computer case 1 of the present invention comprises:

a first outer board 10, the first outer board 10 is in a plate shape, is located at an exterior side of the computer case 1, and is provided with plural through-holes 11;

a second outer board 20, the second outer board 20 is in a plate shape, is located at the other exterior side of the computer case 1, and is provided with plural through-holes 21;

plural inner boards 30, the inner boards 30 are assembled between the first and second outer board 10, 20, with that relative positions of the inner boards 30 corresponding to the through-holes 11, 21 of the first and second outer board 10, 20 are also provided with through-holes 31, and the inner boards 30 are preferably made by a plate-shaped aluminum material, although other metals can be used as the board material as well;

plural sleeves 40, the sleeves 40 are located respectively between the neighboring inner boards 30 or between the first, second outer board 10, 20 and their neighboring inner boards 30; and

plural pillars 50, the pillars 50 are a locking device.

The pillars 50 can be installed by two ways. The first way is to install the pillars 50 at four corners of the computer case 1. The pillars 50 penetrate respectively the through-holes 11 of the first outer board 10, the through-holes 31 of the inner boards 30, the neighboring sleeves 40 and the through-holes 21 of the second outer board 20. Bolts 51, 52 at a left and to right side of the pillar 50 protrude respectively at the exterior sides of the first and second outer board 10, 20 and the protruded bolts 51, 52 are locked respectively with an upper nut 60 to accomplish assembling the computer case 1.

The second way is to install the pillars 50 at the four corners of the computer case 1. The pillars 50 penetrate respectively the through-holes 31 of the inner board 30 and the neighboring sleeves 40. The bolts 51, 52 that protrude at the left and right side of the pillar 50 are locked respectively with the upper nut 60 to position the inner boards 30.

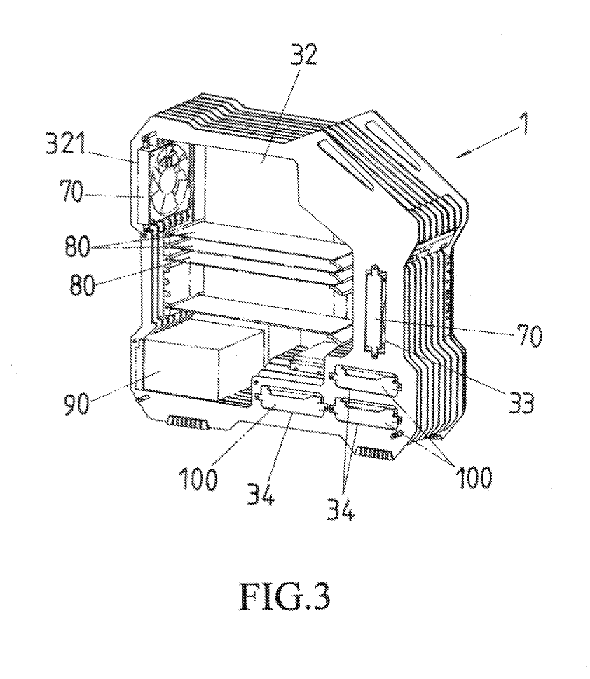

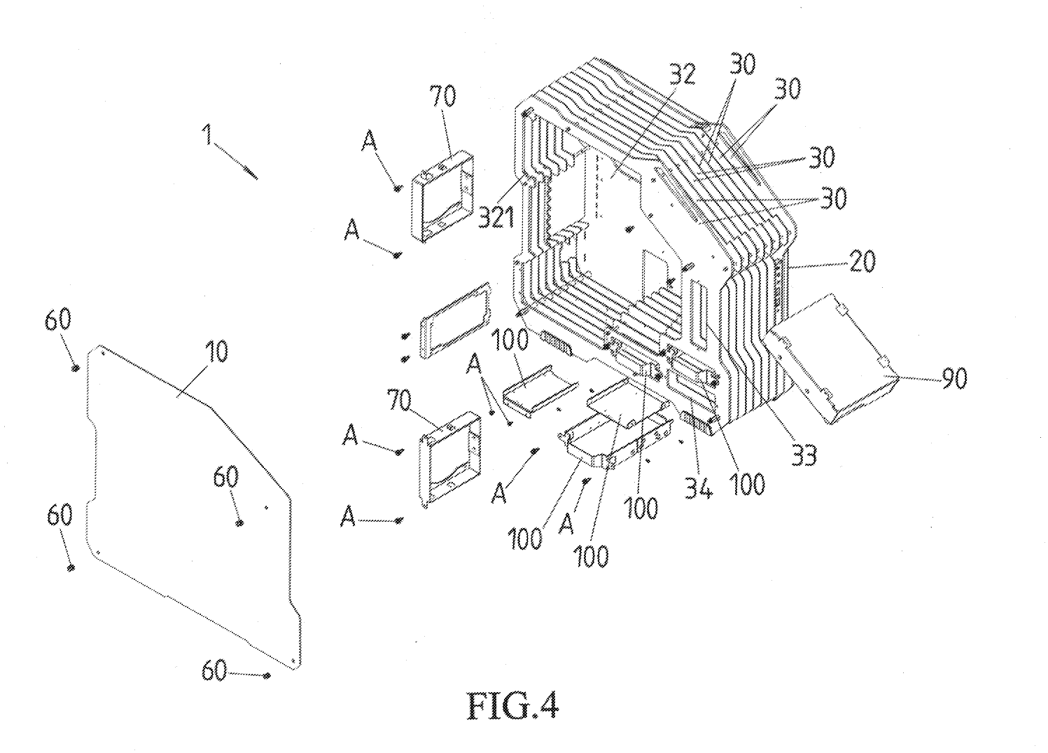

As shown in FIG. 3 and FIG. 4, an exterior of each inner board 30 is provided with a holding space 32. An upper-left corner of the holding space 32 is formed with an L-shaped fan seat 321 to accommodate a fan 70 and the fan seat 321 is locked on the inner board 30 by screws A. An upper and lower part in the holding space 32 is transversally provided with plural circuit boards 80 and a lower-left corner of the holding space 32 is installed with a power supply 90. On the other hand, a front plate of the inner board 30 is provided with a fan slot 33 to accommodate the fan 70. Three slot holes 34 at a lower end of the fan slot 33 can be installed with HDDs (Hard Disk Drives) 100; whereas, the fan 70 and the HDDs 100 can be locked on the inner board 30 by the screws A.

The abovementioned internal parts of the computer case 1 can be assembled as per a user's request. The computer case 1 can be assembled by one inner board 30, wherein the first and second outer board 10, 20 can be assembled with the inner board 30, acting as a left and right board; or, the first and second outer board 10, 20 can be also assembled with the inner board 30, acting as an upper and lower board. Upper, lower, left and right sides of the computer case 1 that is assembled by one inner board 30 are all opened to air, which is able to improve cooling and heat dissipation effects of the computer.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A computer case with ventilation and heat dissipation effects comprising:
a first outer board, the first outer board is in a plate shape, is located at an exterior side of the computer case, and is provided with plural through-holes;
a second outer board, the second outer board is in a plate shape, is located at the other exterior side of the computer case, and is provided with plural through-holes;
plural inner boards, the inner boards are assembled between the first and second outer board, with that relative positions of the inner boards corresponding to the through-holes of the first and second outer board are provided with plural through-holes, and an interior of each inner board is provided with a holding space and plural slot holes;
plural sleeves, the sleeves are located respectively between the neighboring inner boards or between the first, second outer board and their neighboring inner boards; and
plural pillars, the pillars penetrate respectively the through-holes of the first outer board, the second outer board, the inner boards and the neighboring sleeves to fix the plural inner boards.

2. The computer case with ventilation and heat dissipation effects according to claim 1, wherein the holding space of the inner board is provided with a fan seat to accommodate a fan.

3. The computer case with ventilation and heat dissipation effects according to claim 1, wherein one slot hole of the inner board is installed with a fan and the rest of slot holes are installed with hard disk drives.

4. The computer case with ventilation and heat dissipation effects according to claim 1, wherein a left and right side of the pillar is provided respectively with a bolt, and the bolts that protrude at exteriors of the left and right side of the pillar are locked respectively with an upper nut for positioning.
